(19) United States
(12) Patent Application Publication
(10) Pub. No.: US 2024/0092221 A1
(43) Pub. Date: Mar. 21, 2024

(54) METHOD FOR DETERMINING AN OPTIMAL STATE-OF-CHARGE OPERATING WINDOW FOR A BATTERY

(71) Applicant: GM GLOBAL TECHNOLOGY OPERATIONS LLC, Detroit, MI (US)

(72) Inventors: Ciro A. Spigno, JR., Leonard, MI (US); Christopher R. Neuman, Denver, CO (US)

(73) Assignee: GM GLOBAL TECHNOLOGY OPERATIONS LLC, Detroit, MI (US)

(21) Appl. No.: 17/948,579

(22) Filed: Sep. 20, 2022

(51) Int. Cl. B60L 58/13; G06N 3/04

(52) U.S. Cl. CPC B60L 58/13; G06N 3/049; B60L 2260/46; B60L 2260/54

(57) ABSTRACT

A method for determining an optimal state-of-charge (SOC) operating window for a battery for use in an electric vehicle includes learning a pattern of periodic charging of the battery for a plurality of time periods and a pattern of periodic usage of the battery for the plurality of time periods, determining a periodic energy requirement for the battery for the plurality of time periods based on the learned patterns using a statistical model, and setting a maximum SOC level and a minimum SOC level for the SOC operating window based on two or more of the periodic energy requirement, the learned patterns and a battery chemistry of the battery.

### INTRODUCTION

This disclosure relates to methods for determining an optimal state-of-charge (SOC) operating window for a battery.

Battery systems in electric vehicles and other applications often include a battery management system implemented in hardware and/or software. One aspect of a battery management system may be an SOC operating window having recommended maximum and minimum SOC levels, which are often set at the factory and which remain constant over the service life of the battery system.

### SUMMARY

According to one embodiment, a method for determining an optimal SOC operating window for a battery for use in an electric vehicle includes learning a pattern of periodic charging of the battery for a plurality of time periods and a pattern of periodic usage of the battery for the plurality of time periods, determining a periodic energy requirement for the battery for the plurality of time periods based on the learned patterns using a statistical model, and setting a maximum SOC level and a minimum SOC level for the SOC operating window based on two or more of the periodic energy requirement, the learned patterns and a battery chemistry of the battery.

In this embodiment, the periodic charging, the periodic usage and the periodic energy requirement may each have a periodicity of daily, weekly or monthly, and the statistical model may be a Weibull distribution, a log-normal distribution or a positively skewed parametric or nonparametric distribution. Additionally, the periodic energy requirement may be a total energy requirement for all of the plurality of time periods, or a plurality of individual energy requirements wherein each of the individual energy requirements corresponds to a respective one of the plurality of time periods.

The learning step may include receiving a plurality of charging instances and a plurality of usage instances for the plurality of time periods, and establishing the patterns of periodic charging and periodic usage based on the received pluralities of charging instances and usage instances, respectively. Each charging instance may include two or more of a respective charging start time, a respective charging end time, a respective charging duration, a respective charging level, a respective beginning battery charge level and a respective ending battery charge level, and each usage instance may include two or more of a respective usage start time, a respective usage end time, a respective usage duration, a respective average energy use amount and a respective total energy use amount.

The method may further include accumulating additional instances of the periodic charging and the periodic usage of the battery, and utilizing a machine learning method to derive an updated maximum SOC level and an updated minimum SOC level for the SOC operating window based on the additional instances of periodic charging and periodic usage. In this configuration, the machine learning method may be a neural network, and the neural network may be a recurrent neural network.

The step of setting the maximum and minimum SOC levels may include: (i) selecting, as a candidate maximum SOC level, a lesser of a first recommended maximum SOC level based on a battery capacity model for the battery and a second recommended maximum SOC level based on a point of diminishing returns for thermal propagation performance for the battery; (ii) selecting, as a candidate minimum SOC level, a recommended minimum SOC level based on the battery capacity model for the battery; (iii) deriving a battery energy requirement by adding a factor to the periodic energy requirement or by multiplying the periodic energy requirement by a multiplier, wherein the factor and the multiplier are each based on the periodic charging of the battery and an availability of charging locations for the battery; and (iv) adjusting one or both of the candidate minimum and maximum SOC levels to establish the minimum and maximum SOC levels, respectively, so as to enable the battery to supply the battery energy requirement. In this arrangement, the battery capacity model may be based on a battery chemistry of the battery, and the availability of charging locations for the battery may be based on a range within which the battery may be utilized to motively power the electric vehicle.

According to another embodiment, a method for determining an optimal SOC operating window for a battery for use in an electric vehicle includes: (i) receiving a plurality of charging instances of the battery for a plurality of time periods and a plurality of usage instances of the battery for the plurality of time periods; (ii) establishing a pattern of periodic charging of the battery based on the received plurality of charging instances and a pattern of periodic usage of the battery based on the received plurality of usage instances; (iii) determining a periodic energy requirement for the battery for the plurality of time periods based on the learned patterns of periodic charging and periodic usage using a positively skewed parametric or nonparametric distribution; (iv) setting a maximum SOC level and a minimum SOC level for the SOC operating window based on two or more of the periodic energy requirement, the learned patterns of periodic charging and periodic usage and a battery chemistry of the battery; (v) accumulating additional instances of the periodic charging and the periodic usage of the battery; and (vi) utilizing a recurrent neural network to derive an updated maximum SOC level and an updated minimum SOC level for the SOC operating window based on the additional instances of periodic charging and periodic usage.

Each charging instance may include two or more of a respective charging start time, a respective charging end time, a respective charging duration, a respective charging level, a respective beginning battery charge level and a respective ending battery charge level, and each usage instance may include two or more of a respective usage start time, a respective usage end time, a respective usage duration, a respective average energy use amount and a respective total energy use amount.

In this embodiment, the step of setting the maximum and minimum SOC levels may include: selecting, as a candidate maximum SOC level, a lesser of a first recommended maximum SOC level based on a battery capacity model for the battery and a second recommended maximum SOC level based on a point of diminishing returns for thermal propagation performance for the battery; selecting, as a candidate recommended minimum SOC level, a minimum SOC level based on the battery capacity model for the battery; deriving a battery energy requirement by adding a factor to the periodic energy requirement or by multiplying the periodic energy requirement by a multiplier, wherein the factor and the multiplier are each based on the periodic charging of the battery and an availability of charging locations for the battery; and adjusting one or both of the candidate minimum and maximum SOC levels to establish the minimum and maximum SOC levels, respectively, so as to enable the battery to supply the battery energy requirement.

The battery capacity model may be based on a battery chemistry of the battery, and the availability of charging locations for the battery may be based on a range within which the battery may be utilized to motively power the electric vehicle. Additionally, the periodic energy requirement may be one of a total energy requirement for all of the plurality of time periods, and a plurality of individual energy requirements wherein each of the individual energy requirements corresponds to a respective one of the plurality of time periods.

According to yet another embodiment, a method for determining an optimal SOC operating window for a battery for use in an electric vehicle includes: (i) learning a pattern of periodic charging of the battery for a plurality of time periods and a pattern of periodic usage of the battery for the plurality of time periods; (ii) determining a periodic energy requirement for the battery for the plurality of time periods based on the learned patterns using a positively skewed parametric or nonparametric distribution; (iii) setting a maximum SOC level and a minimum SOC level for the SOC operating window based on two or more of the periodic energy requirement, the learned patterns and a battery chemistry of the battery; (iv) accumulating additional instances of the periodic charging and the periodic usage of the battery; and (v) utilizing a recurrent neural network to derive an updated maximum SOC level and an updated minimum SOC level for the SOC operating window based on the additional instances of periodic charging and periodic usage.

In this configuration, the learning step may include: receiving a plurality of charging instances and a plurality of usage instances for the plurality of time periods (wherein each charging instance includes two or more of a respective charging start time, a respective charging end time, a respective charging duration, a respective charging level, a respective beginning battery charge level and a respective ending battery charge level, and wherein each usage instance includes two or more of a respective usage start time, a respective usage end time, a respective usage duration, a respective average energy use amount and a respective total energy use amount); and establishing the patterns of periodic charging and periodic usage based on the received pluralities of charging instances and usage instances, respectively.

Additionally in this configuration, the step of setting the maximum and minimum SOC levels may include: selecting, as a candidate maximum SOC level, a lesser of a first recommended maximum SOC level based on a battery capacity model for the battery and a second recommended maximum SOC level based on a point of diminishing returns for thermal propagation performance for the battery; selecting, as a candidate recommended minimum SOC level, a minimum SOC level based on the battery capacity model for the battery; deriving a battery energy requirement by adding a factor to the periodic energy requirement or by multiplying the periodic energy requirement by a multiplier, wherein the factor and the multiplier are each based on the periodic charging of the battery and an availability of charging locations for the battery; and adjusting one or both of the candidate minimum and maximum SOC levels to establish the minimum and maximum SOC levels, respectively, so as to enable the battery to supply the battery energy requirement; wherein the battery capacity model is based on a battery chemistry of the battery, and wherein the availability of charging locations for the battery is based on a range within which the battery may be utilized to motively power the electric vehicle.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

FIG. 1 is a diagram illustrating an SOC operating window for a battery.

FIG. 2 is a block diagram of a system for determining an optimal SOC operating window for a battery for use in an electric vehicle.

FIG. 3 is a diagram illustrating the occurrence of periodic charging and periodic usage of a battery in an electric vehicle over multiple time periods.

FIG. 4 is a flowchart of a method for determining an optimal SOC operating window for a battery for use in an electric vehicle.

FIG. 5 is a block diagram showing various inputs and outputs for a portion of the method illustrated in FIG. 4.

FIG. 6 is a block diagram showing various aspects of periodic charging.

FIG. 7 is a block diagram showing various aspects of periodic usage.

FIG. 8 is a block diagram showing various types of machine learning methods.

FIG. 9 is a block diagram showing various types of statistical models.

FIG. 10 is a block diagram showing various types of periodicity.

### DETAILED DESCRIPTION

Referring now to the drawings, wherein like numerals indicate like parts in the several views, a method 100 for determining an optimal SOC operating window 20 for a battery 10 for use in an electric vehicle 18 is shown and described herein.

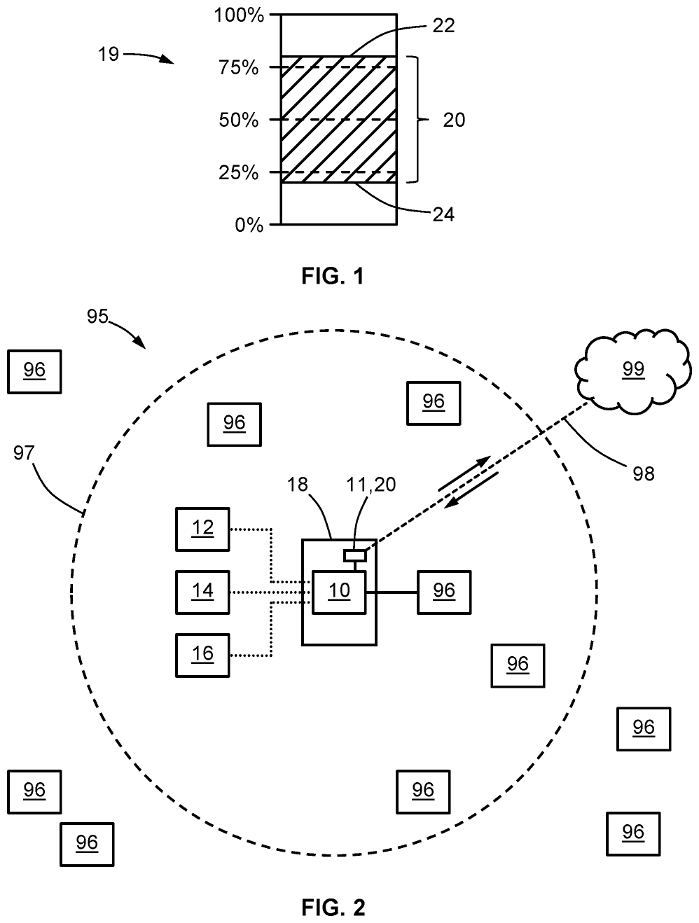

FIG. 1 is a diagram showing an SOC operating window 20 for a battery 10, and FIG. 2 is a block diagram of a system for determining an optimal SOC operating window 20 for the battery 10 for use in an electric vehicle 18.

In FIG. 1, an energy level meter 19 is shown having a range from 0% (corresponding to the battery 10 being fully discharged) to 100% (corresponding to the battery 10 being fully charged). Also shown is an optimal SOC operating window 20 having a maximum SOC level 22 and a minimum SOC level 24. Note for the optimal maximum SOC level 22 may be less than 100% of the battery's full capacity, and the optimal minimum SOC level 24 may be greater than the 0% or fully discharged level. This is because each type of battery 10 has its own battery chemistry 12, such as lithium iron phosphate (LiFePO₄), lithium cobalt oxide (LCO), nickel metal hydride (NiNM), nickel cobalt manganese aluminum (NCMA), etc., and each type of battery chemistry 12 has its own particular maximum and minimum levels 22, 24 for what the SOC range should be for that battery chemistry 12.

In practice, it is ideal to maintain the SOC for a battery 10 within a range between the maximum and minimum SOC levels 22, 24, and to avoid overcharging the battery 10 above the maximum SOC level 22 and to avoid allowing the SOC to drop below the minimum SOC level 24, as this will help prolong the effective service life of the battery 10. Each battery 10 or battery type may also have its own particular battery capacity model 14 and point of diminishing returns for thermal propagation performance 16, as illustrated in FIG. 2. Alternatively, a given battery capacity model 14 may be adapted or parameterized so as to fit or accommodate the battery chemistry 12 of a battery 10, thereby enabling the battery capacity model 14 to reliably predict the performance characteristics of the modeled battery 10.

In FIG. 2, the battery 10 is shown aboard an electric vehicle 18 (which may include hybrid electric vehicles). In addition to the battery 10, the vehicle 18 includes a controller 11, which holds the SOC operating window 20. The controller 11 may be configured to directly or indirectly communicate with the cloud 99 (e.g., via one-way or two-way telemetry 98 such as cell signals, satellite signals, radio signals, etc.). The controller 11 may include or have access to hardware, circuitry, firmware and software so as to enable the controller 11 to calculate or determine the SOC operating window 20 onboard the vehicle 18 and/or to receive the SOC operating window 20 from the cloud 99 (which may include back-office calculation, tracking and monitoring capabilities). The vehicle 18 may have a range 97 within which the vehicle 18 may be motively powered by the battery 10. This range 97 may be defined by a radius from the vehicle 18 as illustrated by the circular area in FIG. 2, or it may be defined by a non-circular area that depends on factors such as road grade, road type, road conditions and the like. In either case, the extent or size of the range 97 will depend on the current energy level of the battery 10; thus, the higher the battery energy level of the battery 10, the larger the then-current range 97 will be, with the range 97 shrinking as the battery energy level decreases. Note that the vehicle 18 is shown as being connected to a charging station 96, with four other charging stations 96 within the range 97 and five other charging stations 96 outside of the range 97. The availability 95 of these charging stations 96 include the respective locations of these stations 96 and whether each station 96 is currently and foreseeably in-service and available for charging the vehicle 18.

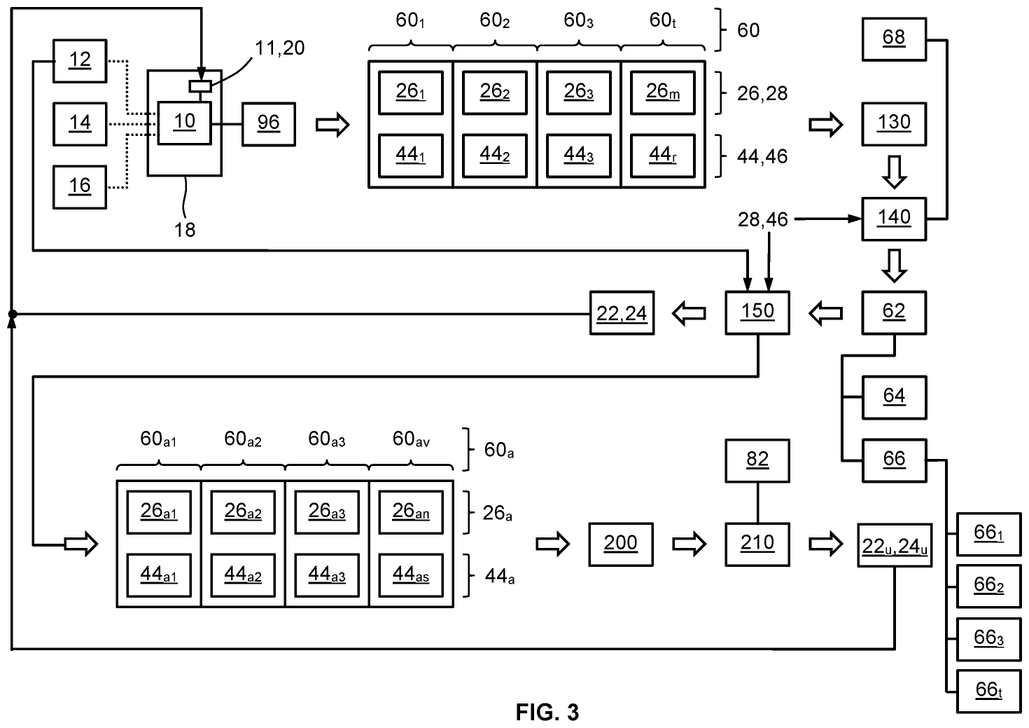

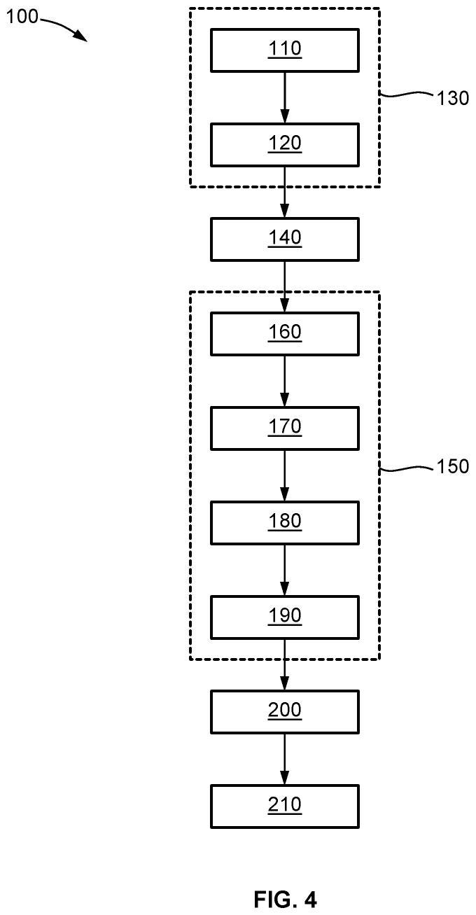

FIG. 3 shows a diagram illustrating the occurrence of multiple instances of periodic charging 26 and periodic usage 44 of the battery 10 in an electric vehicle 18 over multiple time periods 60, and FIG. 4 shows a flowchart of a method 100 for determining an optimal SOC operating window 20 for the battery 10. Starting at the upper-left of FIG. 3, the battery 10 and vehicle 18 are shown, with the battery 10 being charged by a charging station 96. Moving rightward to the upper-center of the drawing, a series of individual time periods 60₁, 60₂, 60₃, 60ₜ are shown. Here, the subscript “t” represents a determined number of time periods 60; this may be a total of four time periods 60 as shown here, or it may be any other number of time periods 60 (e.g., 20, 100, 1000, etc.).

The length of each time period 60 may be predetermined or it may be arbitrarily chosen on-the-fly. For example, as illustrated in FIG. 10, each time period 60 may have a periodicity 76 of daily 77, weekly 78, monthly 79 or any other periodic measurement 80 (including those which are more frequent than daily 77, such as hourly, and those which are less frequent than monthly 79, such as quarterly). The other periodic measurement 80 may also include time periods 60 which are not single units of customary temporal measurement. For example, the other periodic measurement 80 may be every two hours, every half-hour, every twenty minutes, every three days and so forth. The periodic charging 26, the periodic usage 44 and the periodic energy requirement 62 may all have the same periodicity 76, or they may all have different periodicities 76 from each other, or two of them may have the same periodicity 76 while the other of them may has a different periodicity 76 from the other two.

Returning to the upper-center of FIG. 3, it may be seen that each time period 60 contains a respective periodic charging 26 (also sometimes referred to herein as a “charging instance” or an “individual charging instance”) and a respective periodic usage 44 (also sometimes referred to herein as a “usage instance” or an “individual usage instance”). Specifically, four individual charging instances 26₁, 26₂, 26₃, 26ₘ are shown, which form a pattern 28 of periodic charging 26, and four individual usage instances 44₁, 44₂, 44₃, 44ᵣ are shown, which form a pattern 46 of periodic usage 44. Here, the subscript “m” represents a determined number of charging instances 26; this may be a total of four charging instances 26 as shown here, or it may be any other number of charging instances 26. Similarly, the subscript “r” represents a determined number of usage instances 44; this may be a total of four usage instances 44 as shown here, or it may be any other number of usage instances 44. Note that while FIG. 3 shows one charging instance 26 and one usage instance 44 in each time period 60, this is merely for illustration purposes, as there may be any combination of charging instances 26 and usage instances 44 in each time period 60 (including no charging instance 26 and/or no usage instance 44 in any particular time period 60). Thus, the pattern 28 of charging instances 26 and the pattern 46 of usage instances 44 do not necessarily have to match each other.

Moving on to the upper-right of FIG. 3, a step or block 130 is presented, which is also shown as a dashed rectangle in the process flow presented in FIG. 4. At block 130, the patterns 28, 46 of periodic charging 26 and periodic usage 44 of the battery 10 for the plurality of time periods 60 is learned, such as by the controller 11 and/or by way of telemetry/telecommunications 98 with resources in the cloud 99. Next, at block 140, a periodic energy requirement 62 for the battery 10 for the plurality of time periods 60 is determined, based on the learned patterns 28, 46 using an appropriate statistical model 68. Then, at block 150 (which is shown as a dashed rectangle in FIG. 4), a maximum SOC level 22 and a minimum SOC level 24 for the SOC operating window 20 are set, based on two or more of the periodic energy requirement 62, the learned patterns 28, 46 and the battery chemistry 12 of the battery 10. As illustrated in FIG. 3, the maximum and minimum SOC levels 22, 24 for the SOC operating window 20 may be inputted into or made accessible to the controller 11.

In some configurations, the periodic energy requirement 62 may be a total energy requirement 64 for all of the plurality of time periods 60 taken together. For example, the total energy requirement 64 for the four time periods 60 shown in FIG. 3 may be a sum of all the individual usage instances 44₁, 44₂, 44₃, 44ᵣ, and optionally may also include an adjustment to this sum (e.g., a subtraction from this sum) based on the individual charging instances 26₁, 26₂, 26₃, 26ₘ. Alternatively, the periodic energy requirement 62 may be a plurality or set of individual energy requirements 66—e.g., 66₁, 66₂, 66₃, 66ₜ, as illustrated in the lower-right portion of FIG. 3—wherein each of the individual energy requirements 66 corresponds to a respective one of the plurality of time periods 60. In either case, the periodic energy requirement 62 may also include or be based on additional factors, such as the battery chemistry 12, etc.

As illustrated in FIG. 9, the statistical model 68 used in conjunction with block 140 may be a Weibull distribution 70, a log-normal distribution 71, a positively skewed parametric or nonparametric distribution 72 or some other suitable statistical model 74 that is a continuous probability distribution. For example, a Weibull distribution 70 may have a distribution that is governed by the expression

$$f ( x ) = \frac{k}{λ} {( \frac{x}{λ} )}^{k - 1} {e}^{- {( \frac{x}{λ} )}^{k}} ,$$

where k>0 is a shape parameter, λ>0 is a scale parameter, the independent variable x is a measure of battery energy (e.g., in kilowatt-hours) and f(x) is a density.

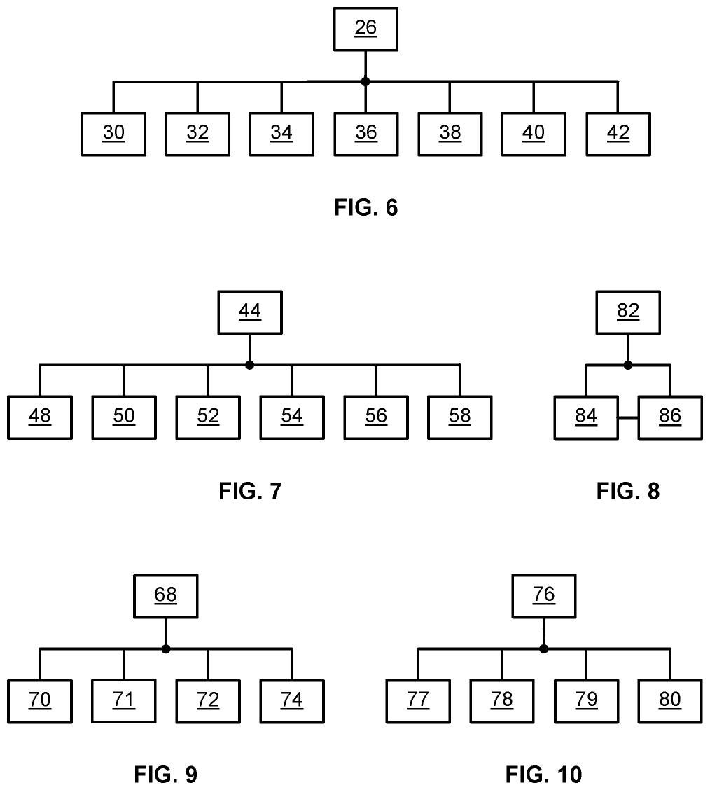

As shown in FIG. 4, the learning step at block 130 may include, at block 110, a step of receiving or accumulating the plurality of charging instances 26 and the plurality of usage instances 44 for the plurality of time periods 60, and, at block 120, a step of establishing the patterns 28, 46 of periodic charging 26 and periodic usage 44 based on the received or accumulated pluralities of charging instances 26 and usage instances 44, respectively. As illustrated in FIG. 6, each charging instance 26 may include two or more of a respective charging start time 30, a respective charging end time 32, a respective charging duration 34 (e.g., as measured from the respective charging start time 30 to the respective end time 32), a respective charging level 36, a respective beginning battery charge level 38, a respective ending battery charge level 40 and any other suitable aspect or measure 42 of the charging instances 26. Further, as illustrated in FIG. 7, each usage instance 44 may include two or more of a respective usage start time 48, a respective usage end time 50, a respective usage duration 52, a respective average energy use amount 54, a respective total energy use amount 56 and any other suitable aspect or measure 58 of the usage instances 44.

Returning again to FIGS. 3 and 4, the method 100 may further include, at block 200, accumulating additional instances 26a, 44a of the periodic charging 26 and the periodic usage 44 of the battery 10, and, at block 210, utilizing a machine learning method 82 to derive an updated maximum SOC level 22u and an updated minimum SOC level 24u for the SOC operating window 20 based on the additional instances 26a, 44a of periodic charging 26 and periodic usage 44. As exemplified at the lower-left of FIG. 3, the accumulation of additional instances 26a, 44a of charging instances 26 (e.g., 26ₐ₁, 26ₐ₂, 26ₐ₃, 26ₐₙ) and usage instances 44 (e.g., 44ₐ₁, 44ₐ₂, 44ₐ₃, 44ₐₛ) may cover or occur over a plurality of additional time periods 60ₐ, such as 60ₐ₁, 60ₐ₂, 60ₐ₃ and 60ₐᵥ as shown. Here, the subscript “a” represents an “additional” time period 60ₐ, charging instance 26ₐ or usage instance 44ₐ, the subscript “v” represents a determined or indeterminate number of additional time periods 60ₐ (where the subscripts “t” and “v” may be different from each other), the subscript “n” represents a determined or indeterminate number of additional charging instances 26ₐ (where the subscripts “m” and “n” may be different from each other), and the subscript “s” represents a determined or indeterminate number of additional usage instances 44ₐ (where the subscripts “r” and “s” may be different from each other). The number of additional time periods 60ₐ may be a total of four additional time periods 60ₐ as shown in FIG. 3, or it may be any other number of additional time periods 60ₐ, including an open-ended number of additional time periods 60ₐ over which additional instances 26ₐ, 44ₐ may continue to be accumulated.

Note that while FIG. 3 shows one additional charging instance 26a and one additional usage instance 44a in each additional time period 60a, this is merely for illustration purposes, as there may be any combination of additional charging instances 26ₐ and additional usage instances 44a in each additional time period 60a (including no additional charging instance 26a and/or no additional usage instance 44a in any particular additional time period 60a). Thus, any patterns of additional charging instances 26ₐ and additional usage instances 44ₐ do not necessarily have to match each other.

Because of the potential open-endedness of the number of additional charging instances 26ₐ and additional usage instances 44ₐ that are accumulated and utilized in the potentially open-ended number of additional time periods 60ₐ in blocks 200 and 210, a machine learning method 82 may be well suited to this task. As illustrated in FIG. 8, the machine learning method 82 may be a neural network 84, and the neural network 84 may be a recurrent neural network 86. Note that the horizontal line connecting reference numerals 84 and 86 in FIG. 8 denotes that the neural network 84 may be a recurrent neural network 86, while the combination of horizontal and vertical lines connecting reference numerals 82 and 86 denotes that the machine learning method 82 may directly include a recurrent neural network 86.

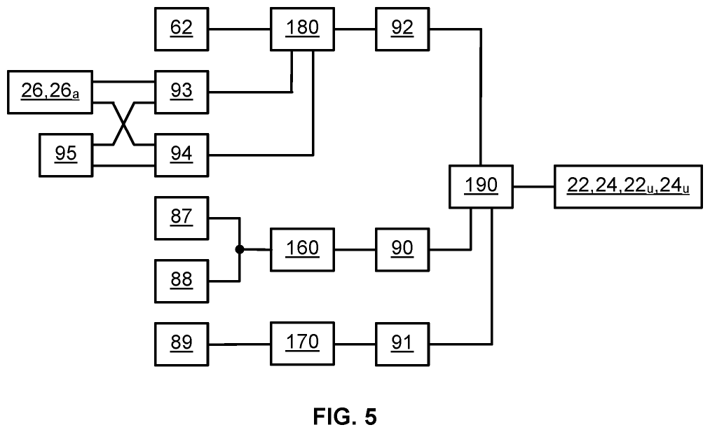

As shown in FIG. 4, the step of setting the maximum and minimum SOC levels 22, 24 at block 150 may include blocks 160, 170, 180 and 190. These blocks 160, 170, 180, 190 may be viewed in more detail in FIG. 5, which shows a block diagram of various inputs and outputs for these particular steps. At block 160, the lesser of a first recommended maximum SOC level 87 (based on a battery capacity model 14 and/or a battery chemistry 12 of the battery 10) and a second recommended maximum SOC level 88 (based on a point of diminishing returns for thermal propagation performance for the battery 10) is selected as a candidate maximum SOC level 90. At block 170, a recommended minimum SOC level 89 (based on a battery capacity model 14 and/or a battery chemistry 12 of the battery 10) is selected as a candidate minimum SOC level 91. At block 180, a battery energy requirement 92 is derived by either of two approaches: by adding a factor 93 to the periodic energy requirement 62, or by multiplying the periodic energy requirement 62 by a multiplier 94. Here, the factor 93 and the multiplier 94 are each based on the periodic charging 26 (and/or the additional periodic charging 26ₐ) of the battery 10 and on an availability 95 of charging locations 96 for the battery 10; thus, the factor 93 and the multiplier 94 may each be viewed as an “anxiety factor”. (For example, a history of frequent periodic charging/additional periodic charging 26, 26ₐ in combination with a low availability 95 of charging locations 96 may produce more “anxiety” for the owner of the battery/electric vehicle 10, 18, and thus a relatively higher factor/multiplier 93, 94, than would be the case for a history of less frequent periodic charging/additional periodic charging 26, 26ₐ in combination with a high availability 95 of charging locations 96.) And finally at block 190, one or both of the candidate minimum and maximum SOC levels 91, 90 is/are adjusted in order to establish the minimum and maximum SOC levels 24, 22, respectively, in such a way so as to enable the battery 10 to supply the derived battery energy requirement 92. In this arrangement, the battery capacity model 14 may be based on a battery chemistry 12 of the battery 10, and the availability 95 of charging locations 96 for the battery 10 may be based on a range 97 within which the battery 10 may be utilized to motively power the electric vehicle 18. Note that blocks 160-190 may also apply to the use of additional periodic charging 26ₐ in order to establish or produce the updated minimum and maximum SOC levels 24ᵤ, 22ᵤ, such as in conjunction with blocks 200-210.

According to another embodiment, a method 100 for determining an optimal SOC operating window 20 for a battery 10 for use in an electric vehicle 18 includes: (i) at block 110, receiving or accumulating a plurality of charging instances 26 of the battery 10 for a plurality of time periods 60 and a plurality of usage instances 44 of the battery 10 for the plurality of time periods 60; (ii) at block 120, establishing a pattern 28 of periodic charging 26 of the battery 10 based on the received or accumulated plurality of charging instances 26 and a pattern 46 of periodic usage 44 of the battery 10 based on the received or accumulated plurality of usage instances 44; (iii) at block 140, determining a periodic energy requirement 62 for the battery 10 for the plurality of time periods 60 based on the learned patterns 28, 46 of periodic charging 26 and periodic usage 44 using a positively skewed parametric or nonparametric distribution 72; (iv) at block 150, setting a maximum SOC level 22 and a minimum SOC level 24 for the SOC operating window 20 based on two or more of the periodic energy requirement 62, the learned patterns 28, 46 of periodic charging 26 and periodic usage 44 and a battery chemistry 12 of the battery 10; (v) at block 200, accumulating additional instances 26ₐ, 44ₐ of the periodic charging 26 and the periodic usage 44 of the battery 10; and (vi) at block 210, utilizing a recurrent neural network 86 to derive an updated maximum SOC level 22ᵤ and an updated minimum SOC level 24ᵤ for the SOC operating window 20 based on the additional instances 26ₐ, 44ₐ of periodic charging 26 and periodic usage 44.

Each charging instance 26 may include two or more of a respective charging start time 30, a respective charging end time 32, a respective charging duration 34, a respective charging level 36, a respective beginning battery charge level 38 and a respective ending battery charge level 40, and each usage instance 44 may include two or more of a respective usage start time 48, a respective usage end time 50, a respective usage duration 52, a respective average energy use amount 54 and a respective total energy use amount 56.

In this embodiment, the step of setting the maximum and minimum SOC levels 22, 24 (i.e., at block 150) may include: at block 160, selecting, as a candidate maximum SOC level 90, a lesser of a first recommended maximum SOC level 87 based on a battery capacity model 14 for the battery 10 and a second recommended maximum SOC level 88 based on a point of diminishing returns for thermal propagation performance 16 for the battery 10; at block 170, selecting, as a candidate minimum SOC level 91, a recommended minimum SOC level 89 based on the battery capacity model 14 for the battery 10; at block 180, deriving a battery energy requirement 92 by adding a factor 93 to the periodic energy requirement 62 or by multiplying the periodic energy requirement 62 by a multiplier 94, wherein the factor 93 and the multiplier 94 are each based on the periodic charging 26 of the battery 10 and an availability 95 of charging locations 96 for the battery 10; and at block 190, adjusting one or both of the candidate minimum and maximum SOC levels 91, 90 to establish the minimum and maximum SOC levels 24, 22, respectively, so as to enable the battery 10 to supply the battery energy requirement 92.

The battery capacity model 14 may be based on a battery chemistry 12 of the battery 10, and the availability 95 of charging locations 96 for the battery 10 may be based on a range 97 within which the battery 10 may be utilized to motively power the electric vehicle 18. Additionally, the periodic energy requirement 62 may be one of a total energy requirement 64 for all of the plurality of time periods 60, and a plurality of individual energy requirements 66 wherein each of the individual energy requirements 66 corresponds to a respective one of the plurality of time periods 60.

According to yet another embodiment, a method 100 for determining an optimal SOC operating window 20 for a battery 10 for use in an electric vehicle 18 includes: (i) at block 130, learning a pattern 28 of periodic charging 26 of the battery 10 for a plurality of time periods 60 and a pattern 46 of periodic usage 44 of the battery 10 for the plurality of time periods 60; (ii) at block 140, determining a periodic energy requirement 62 for the battery 10 for the plurality of time periods 60 based on the learned patterns 28, 46 using a positively skewed parametric or nonparametric distribution 72; (iii) at block 150, setting a maximum SOC level 22 and a minimum SOC level 24 for the SOC operating window 20 based on two or more of the periodic energy requirement 62, the learned patterns 28, 46 and a battery chemistry 12 of the battery 10; (iv) at block 200, accumulating additional instances 26ₐ, 44ₐ of the periodic charging 26 and the periodic usage 44 of the battery 10; and (v) at block 210, utilizing a recurrent neural network 86 to derive an updated maximum SOC level 22ᵤ and an updated minimum SOC level 24ᵤ for the SOC operating window 20 based on the additional instances 26ₐ, 44ₐ of periodic charging 26 and periodic usage 44.

In this configuration, the learning step 130 may include: at block 110, receiving or accumulating a plurality of charging instances 26 and a plurality of usage instances 44 for the plurality of time periods 60 (wherein each charging instance 26 includes two or more of a respective charging start time 30, a respective charging end time 32, a respective charging duration 34, a respective charging level 36, a respective beginning battery charge level 38 and a respective ending battery charge level 40, and wherein each usage instance 44 includes two or more of a respective usage start time 48, a respective usage end time 50, a respective usage duration 52, a respective average energy use amount 54 and a respective total energy use amount 56); and, at block 120, establishing the patterns 28, 46 of periodic charging 26 and periodic usage 44 based on the received or accumulated pluralities of charging instances 26 and usage instances 44, respectively.

Additionally in this configuration, the step of setting the maximum and minimum SOC levels 22, 24 (i.e., block 150) may include: at block 160, selecting, as a candidate maximum SOC level 90, a lesser of a first recommended maximum SOC level 87 based on a battery capacity model 14 for the battery 10 and a second recommended maximum SOC level 88 based on a point of diminishing returns for thermal propagation performance 16 for the battery 10; at block 170, selecting, as a candidate minimum SOC level 91, a recommended minimum SOC level 89 based on the battery capacity model 14 for the battery 10; at block 180, deriving a battery energy requirement 92 by adding a factor 93 to the periodic energy requirement 62 or by multiplying the periodic energy requirement 62 by a multiplier 94, wherein the factor 93 and the multiplier 94 are each based on the periodic charging 26 of the battery 10 and an availability 95 of charging locations 96 for the battery 10; and at block 190, adjusting one or both of the candidate minimum and maximum SOC levels 91, 90 to establish the minimum and maximum SOC levels 24, 22, respectively, so as to enable the battery 10 to supply the battery energy requirement 92; wherein the battery capacity model 14 is based on a battery chemistry 12 of the battery 10. In this embodiment, the availability 95 of charging locations 96 for the battery 10 is based on a range 97 within which the battery 10 may be utilized to motively power the electric vehicle 18.

Note that any of the foregoing embodiments may include receiving one or more exogenous variables for use in one or more steps of the method 100. For example, an exogenous variable may include the day of the week when charging data or usage data is received or accumulated, as well as the number of miles driven per time period 60, 60ₐ and the average drive efficiency per time period 60, 60ₐ. Additionally, the method 100 may also include one or more of the steps sending data or results to a customer or owner of the battery/electric vehicle 10, 18, soliciting and receiving confirmation or acknowledgment of the sent data/results from the customer/owner, sending an optimized window or display configuration to the battery/vehicle 10, 18 for visual display of information pertaining to the battery 10 within the vehicle 18, and updating or adjusting the visual display of the window/information. Further, the determining step 140 using a statistical model 68 and/or the utilizing/deriving step 210 using a machine learning model 82 may be performed in the cloud and/or on-board the vehicle 18 (i.e., utilizing and/or interfacing with the controller 11).

While various steps of the method 100 have been described as being separate blocks, and various functions of the system have been described as being separate elements, it may be noted that two or more steps may be combined into fewer blocks, and two or more functions may be combined into fewer elements. Similarly, some steps described as a single block may be separated into two or more blocks, and some functions described as a single element may be separated into two or more elements. Additionally, the order of the steps or blocks described herein may be rearranged in one or more different orders, and the arrangement of the functions and elements may be rearranged into one or more different arrangements.

It may be noted that at some points throughout the present disclosure, reference may be made to a singular input, output, element, etc., while at other points reference may be made to plural/multiple inputs, outputs, elements, etc. Thus, weight should not be given to whether the input(s), output(s), element(s), etc. are used in the singular or plural form at any particular point in the present disclosure, as the singular and plural uses of such words should be viewed as being interchangeable, unless the specific context dictates otherwise.

The above description is intended to be illustrative, and not restrictive. While the dimensions and types of materials described herein are intended to be illustrative, they are by no means limiting and are exemplary embodiments. In the following claims, use of the terms “first”, “second”, “top”, “bottom”, etc. are used merely as labels, and are not intended to impose numerical or positional requirements on their objects. As used herein, an element or step recited in the singular and preceded by the word “a” or “an” should be understood as not excluding plural of such elements or steps, unless such exclusion is explicitly stated. Additionally, the phrase “at least one of A and B” and the phrase “A and/or B” should each be understood to mean “only A, only B, or both A and B”. Moreover, unless explicitly stated to the contrary, embodiments “comprising” or “having” an element or a plurality of elements having a particular property may include additional such elements not having that property. And when broadly descriptive adverbs such as “substantially” and “generally” are used herein to modify an adjective, these adverbs mean “mostly”, “mainly”, “for the most part”, “to a significant extent”, “to a large degree” and/or “at least 51 to 99% out of a possible extent of 100%”, and do not necessarily mean “perfectly”, “completely”, “strictly”, “entirely” or “100%”. Additionally, the word “proximate” may be used herein to describe the location of an object or portion thereof with respect to another object or portion thereof, and/or to describe the positional relationship of two objects or their respective portions thereof with respect to each other, and may mean “near”, “adjacent”, “close to”, “close by”, “at” or the like.

This written description uses examples, including the best mode, to enable those skilled in the art to make and use devices, systems and compositions of matter, and to perform methods, according to this disclosure. It is the following claims, including equivalents, which define the scope of the present disclosure.

What is claimed is:

1. A method for determining an optimal state-of-charge (SOC) operating window for a battery for use in an electric vehicle, comprising:
learning a pattern of periodic charging of the battery for a plurality of time periods and a pattern of periodic usage of the battery for the plurality of time periods;
determining a periodic energy requirement for the battery for the plurality of time periods based on the learned patterns using a statistical model; and
setting a maximum SOC level and a minimum SOC level for the SOC operating window based on two or more of the periodic energy requirement, the learned patterns and a battery chemistry of the battery.

2. The method of claim 1, wherein the periodic charging, the periodic usage and the periodic energy requirement each have a periodicity of daily, weekly or monthly.

3. The method of claim 1, wherein the statistical model is a Weibull distribution, a log-normal distribution or a positively skewed parametric or nonparametric distribution.

4. The method of claim 1, wherein the learning step comprises:
receiving a plurality of charging instances and a plurality of usage instances for the plurality of time periods; and
establishing the patterns of periodic charging and periodic usage based on the received pluralities of charging instances and usage instances, respectively.

5. The method of claim 4, wherein each charging instance includes two or more of a respective charging start time, a respective charging end time, a respective charging duration, a respective charging level, a respective beginning battery charge level and a respective ending battery charge level, and wherein each usage instance includes two or more of a respective usage start time, a respective usage end time, a respective usage duration, a respective average energy use amount and a respective total energy use amount.

6. The method of claim 1, further comprising:
accumulating additional instances of the periodic charging and the periodic usage of the battery; and
utilizing a machine learning method to derive an updated maximum SOC level and an updated minimum SOC level for the SOC operating window based on the additional instances of periodic charging and periodic usage.

7. The method of claim 6, wherein the machine learning method is a neural network.

8. The method of claim 7, wherein the neural network is a recurrent neural network.

9. The method of claim 1, wherein the step of setting the maximum and minimum SOC levels comprises:
selecting, as a candidate maximum SOC level, a lesser of a first recommended maximum SOC level based on a battery capacity model for the battery and a second recommended maximum SOC level based on a point of diminishing returns for thermal propagation performance for the battery;
selecting, as a candidate minimum SOC level, a recommended minimum SOC level based on the battery capacity model for the battery;
deriving a battery energy requirement by adding a factor to the periodic energy requirement or by multiplying the periodic energy requirement by a multiplier, wherein the factor and the multiplier are each based on the periodic charging of the battery and an availability of charging locations for the battery; and
adjusting one or both of the candidate minimum and maximum SOC levels to establish the minimum and maximum SOC levels, respectively, so as to enable the battery to supply the battery energy requirement.

10. The method of claim 9, wherein the battery capacity model is based on a battery chemistry of the battery.

11. The method of claim 9, wherein the availability of charging locations for the battery is based on a range within which the battery may be utilized to motively power the electric vehicle.

12. The method of claim 1, wherein the periodic energy requirement is one of:
a total energy requirement for all of the plurality of time periods; and
a plurality of individual energy requirements, wherein each of the individual energy requirements corresponds to a respective one of the plurality of time periods.

13. A method for determining an optimal state-of-charge (SOC) operating window for a battery for use in an electric vehicle, comprising:
receiving a plurality of charging instances of the battery for a plurality of time periods and a plurality of usage instances of the battery for the plurality of time periods;
establishing a pattern of periodic charging of the battery based on the received plurality of charging instances and a pattern of periodic usage of the battery based on the received plurality of usage instances;
determining a periodic energy requirement for the battery for the plurality of time periods based on the learned patterns of periodic charging and periodic usage using a positively skewed parametric or nonparametric distribution;
setting a maximum SOC level and a minimum SOC level for the SOC operating window based on two or more of the periodic energy requirement, the learned patterns of periodic charging and periodic usage and a battery chemistry of the battery;
accumulating additional instances of the periodic charging and the periodic usage of the battery; and
utilizing a recurrent neural network to derive an updated maximum SOC level and an updated minimum SOC level for the SOC operating window based on the additional instances of periodic charging and periodic usage.

14. The method of claim 13, wherein each charging instance includes two or more of a respective charging start time, a respective charging end time, a respective charging duration, a respective charging level, a respective beginning battery charge level and a respective ending battery charge level, and wherein each usage instance includes two or more of a respective usage start time, a respective usage end time, a respective usage duration, a respective average energy use amount and a respective total energy use amount.

15. The method of claim 13, wherein the step of setting the maximum and minimum SOC levels comprises:
selecting, as a candidate maximum SOC level, a lesser of a first recommended maximum SOC level based on a battery capacity model for the battery and a second recommended maximum SOC level based on a point of diminishing returns for thermal propagation performance for the battery;
selecting, as a candidate minimum SOC level, a recommended minimum SOC level based on the battery capacity model for the battery;
deriving a battery energy requirement by adding a factor to the periodic energy requirement or by multiplying the periodic energy requirement by a multiplier, wherein the factor and the multiplier are each based on the periodic charging of the battery and an availability of charging locations for the battery; and
adjusting one or both of the candidate minimum and maximum SOC levels to establish the minimum and maximum SOC levels, respectively, so as to enable the battery to supply the battery energy requirement.

16. The method of claim 15, wherein the battery capacity model is based on a battery chemistry of the battery, and wherein the availability of charging locations for the battery is based on a range within which the battery may be utilized to motively power the electric vehicle.

17. The method of claim 13, wherein the periodic energy requirement is one of:
a total energy requirement for all of the plurality of time periods; and
a plurality of individual energy requirements, wherein each of the individual energy requirements corresponds to a respective one of the plurality of time periods.

18. A method for determining an optimal state-of-charge (SOC) operating window for a battery for use in an electric vehicle, comprising:
learning a pattern of periodic charging of the battery for a plurality of time periods and a pattern of periodic usage of the battery for the plurality of time periods;
determining a periodic energy requirement for the battery for the plurality of time periods based on the learned patterns using a positively skewed parametric or nonparametric distribution;
setting a maximum SOC level and a minimum SOC level for the SOC operating window based on two or more of the periodic energy requirement, the learned patterns and a battery chemistry of the battery;
accumulating additional instances of the periodic charging and the periodic usage of the battery; and
utilizing a recurrent neural network to derive an updated maximum SOC level and an updated minimum SOC level for the SOC operating window based on the additional instances of periodic charging and periodic usage.

19. The method of claim 18, wherein the learning step comprises:
receiving a plurality of charging instances and a plurality of usage instances for the plurality of time periods, wherein each charging instance includes two or more of a respective charging start time, a respective charging end time, a respective charging duration, a respective charging level, a respective beginning battery charge level and a respective ending battery charge level, and wherein each usage instance includes two or more of a respective usage start time, a respective usage end time, a respective usage duration, a respective average energy use amount and a respective total energy use amount; and
establishing the patterns of periodic charging and periodic usage based on the received pluralities of charging instances and usage instances, respectively.

20. The method of claim 18, wherein the step of setting the maximum and minimum SOC levels comprises:
selecting, as a candidate maximum SOC level, a lesser of a first recommended maximum SOC level based on a battery capacity model for the battery and a second recommended maximum SOC level based on a point of diminishing returns for thermal propagation performance for the battery;
selecting, as a candidate minimum SOC level, a recommended minimum SOC level based on the battery capacity model for the battery;
deriving a battery energy requirement by adding a factor to the periodic energy requirement or by multiplying the periodic energy requirement by a multiplier, wherein the factor and the multiplier are each based on the periodic charging of the battery and an availability of charging locations for the battery; and
adjusting one or both of the candidate minimum and maximum SOC levels to establish the minimum and maximum SOC levels, respectively, so as to enable the battery to supply the battery energy requirement;
wherein the battery capacity model is based on a battery chemistry of the battery, and wherein the availability of charging locations for the battery is based on a range within which the battery may be utilized to motively power the electric vehicle.
